(19) United States
(12) Patent Application Publication
(10) Pub. No.: US 2014/0167273 A1
(43) Pub. Date: Jun. 19, 2014

(54) LOW PARASITIC PACKAGE SUBSTRATE HAVING EMBEDDED PASSIVE SUBSTRATE DISCRETE COMPONENTS AND METHOD FOR MAKING SAME

(71) Applicant: QUALCOMM INCORPORATED, San Diego, CA (US)

(72) Inventors: Jonghae Kim, San Diego, CA (US); Chengjie Zuo, Santee, CA (US); Changhan Yun, San Diego, CA (US); Mario Francisco Velez, San Diego, CA (US); Ravindra V. Shenoy, Dublin, CA (US); Matthew M. Nowak, San Diego, CA (US); Francesco Carobolante, San Diego, CA (US); Kyu-Pyung Hwang, San Diego, CA (US); Dong Wook Kim, San Diego, CA (US); Young K. Song, San Diego, CA (US)

(73) Assignee: QUALCOMM INCORPORATED, San Diego, CA (US)

(21) Appl. No.: 13/719,984

(22) Filed: Dec. 19, 2012

(51) Int. Cl. H01L 23/482; H01L 23/00

(52) U.S. Cl. CPC H01L 23/4824; H01L 24/83
USPC 257/773; 438/126

(57) ABSTRACT

One feature pertains to a multi-layer package substrate of an integrated circuit package that comprises a discrete circuit component (DCC) having at least one electrode. The DCC is embedded within an insulator layer, and a via coupling component electrically couples to the electrode. A first portion of the via coupling component extends beyond a first edge of the electrode, and a plurality of vias each having a first end couple to the first via coupling component. At least a first via of the plurality of vias couples to the first portion of the via coupling component that extends beyond the first edge of the electrode. Moreover, the plurality of vias each have a second end that electrically couple to a first outer metal layer, and at least a second portion of the via coupling component is positioned within a first inner metal layer.

### BACKGROUND

1. Field

Various features relate to integrated circuits, and more particularly to integrated circuit package substrates featuring embedded passive discrete components.

2. Background

Modern electronic devices, such as mobile phones, laptop computers, tablets computer devices, etc., often include multiple integrated circuits (ICs) and subsystems on a single printed circuit board (PCB). For example, a PCB, such as a “motherboard,” may include an “applications processor” responsible for executing much of the calculation intensive processes associated with running applications for the electronic device. Another IC, for example a power management integrated circuit (PMIC), may be responsible for providing power (e.g., one or more supply voltages and currents) from a battery to the applications processor and other ICs of the electronic device. The network of passive and active circuit components, such as wires, traces, vias, other conductive components, capacitors, and/or inductors that ultimately deliver the supply voltages and currents from the PMIC to another IC of the electronic device, such as the applications processor, may be collectively known as the “power deliver network.”

The power delivery network (PDN) has losses associated with it due to resistance and other parasitic capacitive and inductive components. Thus, the PDN has an impedance associated with it that varies according to frequency. Minimizing this impedance is imperative for power conservation and energy efficiency of the electronic device. For example, if the applications processor needs a 1 volt nominal supply voltage on chip providing 1 amp of current delivered to it by the PMIC, then the PMIC must output a voltage V_{PM}=((1Ω+Z_{PDN})/(1Ω))*V_{DD}, where Z_{PDN} is the impedance of the PDN and V_{DD} (e.g., 1 volt) is the nominal supply voltage of the applications processor. It follows that even a 300 mΩ impedance at a given frequency results in substantial power loss due to the impedance associated with the PDN.

FIG. 1 illustrates a cross-sectional, schematic view of an IC package 100 found in the prior art. The IC package 100 includes an IC die 102, such as an applications processor for an electronic device. The IC package 100, and in particular, the IC die 102 is supplied power (e.g., provided nominal supply voltages and currents) from a PMIC (not shown) through a PDN (portions of the PDN external to the IC package 100 are not shown).

The IC die 102 is electrically coupled to a multi-layer package substrate 104 below it in a flip-chip style. For example, one or more soldering balls 106 may electrically couple the die 102 to metal traces located within a first metal layer 122 of the package substrate 104. The package substrate 104 may be, for example, a four metal layer laminate substrate.

The package substrate 104 shown includes the first metal layer 122, a second metal layer 124, a third metal layer 126, and a fourth metal layer 128. A plurality of metal vertical interconnect accesses (vias) 108 electrically couple traces of the plurality of metal layers 122, 124, 126, 128 of the package substrate 104 to each other where appropriate. Each of the metal layers 122, 124, 126, 128 are generally separated from one another by a plurality of insulator layers 132, 134, 136 that may be composed of one or more dielectric materials, such as, but not limited to, epoxy resin. In particular, the insulating layer 134 in the middle of the package substrate 104 (e.g., a “core”) is thicker than the other layers and also provides structural rigidity to the package substrate 104.

Notably, the package substrate 104 includes a cavity 135 (indicated by the dashed line box) within its core 134 that houses an embedded passive substrate (EPS) discrete circuit component, such as a capacitor, resistor, or inductor. In the example illustrated, the core 134 houses a discrete capacitor 110 (e.g., “decoupling capacitor”) that helps reduce the impedance at a range of frequencies of the PDN by balancing inductive contributions due to the IC package 100. However, there also exists a significant amount of inductance L_{Trace} associated with the conductive path(s) (e.g., vias, traces, etc.) between the decoupling capacitor 110 and the IC die 102 that substantially raises the impedance at another range (e.g., higher range) of frequencies of the PDN. An on-chip capacitor (not shown) located on the IC die 102 helps balance the inductance L_{Trace} to reduce the maximum impedance of the PDN. Besides balancing the inductance with a capacitor, further reductions in the maximum impedance value of the PDN by directly reducing the inductance value L_{Trace} itself is desirable. Doing so may consequently reduce the size of the aforementioned on-chip capacitor needed to balance the inductance L_{Trace}.

FIG. 2 illustrates a cross-sectional, schematic view of a portion of the package substrate 104 found in the prior art. FIG. 3 illustrates a perspective, schematic view of the capacitor 110 coupled to vias. Referring to FIGS. 2 and 3, the discrete capacitor 110 includes two metal electrodes 202, 204, one at each end of the capacitor 110. For example, each end of the capacitor 110 may be coated with a metal conductor to form the electrodes 202, 204. The electrodes 202, 204 may each have a width w_{E} and a length l_{E}, and a top surface 302, 304. The first electrode 202 is electrically coupled to a trace 206 located within the first metal layer 122 by a via 212, and the second electrode 204 is electrically coupled to a trace 208 located within the first metal layer 122 by another via 214 (See FIG. 2). The vias 212, 214 directly couple to the first and second electrodes 202, 204, respectively.

As shown in FIG. 3, the top surface areas 302, 304 of the electrodes 202, 204 are limited so that only a small number of vias, such as vias 212, 214 can directly couple to them (e.g., one via to each electrode). This limits the performance of the IC 100. Specifically, the parasitic inductance L_{Trace} and the resistance R_{Trace} associated with the conductive path from the capacitor 110 to the IC die 102 is relatively high due to, in part, the limited number of vias 212, 214 that are electrically coupled to the capacitor's electrodes 202, 204.

Moreover, in prior art embedded passive substrate designs, the capacitor's electrodes 202, 204 may electrically couple to traces in only the first and last metal layers 122, 128 (e.g., outer metal layers) of the package substrate 104. Traces that are electrically coupled to power and/or ground nets in the second and third metal layers 124, 126 (e.g., inner metal layers) of the package substrate 104 may not be electrically coupled to the electrodes 202, 204. This may further increase L_{Trace} and/or R_{Trace}.

Thus, there is a need for improved embedded passive substrate (EPS) designs that reduce the inductance and/or resistance associated with one or more conductive paths from an embedded passive substrate discrete component (e.g., decoupling capacitor) to an IC die of an IC package. Reducing this inductance and/or resistance will reduce the impedance of the PDN and increase efficiency of electronic devices featuring ICs having the improved EPS designs.

### SUMMARY

One feature provides a multi-layer package substrate of an integrated circuit package that comprises a discrete circuit component (DCC) having at least one electrode, the DCC embedded at least partially within an insulator layer, a first via coupling component electrically coupled to the electrode, a first portion of the first via coupling component extending beyond a first edge of the electrode, and a plurality of vias each having a first end coupled to the first via coupling component, at least a first via of the plurality of vias coupled to the first portion of the first via coupling component extending beyond the first edge of the electrode. According to one aspect, the first via coupling component increases an available surface area to which the first ends of the plurality of vias are coupled to. According to another aspect, the plurality of vias includes three (3) or more vias. According to yet another aspect, the plurality of vias each have a second end that are electrically coupled to a first outer metal layer, and at least a second portion of the first via coupling component is positioned within a first inner metal layer, wherein the first inner metal layer is closer to the insulator layer than the first outer metal layer.

According to one aspect, the first via coupling component is electrically coupled to a first metal trace within the first inner metal layer that is electrically coupled to a power or ground net. According to another aspect, the multi-layer package substrate further comprises a second via coupling component that is electrically coupled to the electrode, a first portion of the second via coupling component extending beyond a second edge of the electrode, at least a second portion of the second via coupling component positioned within a second inner metal layer, the second via coupling component electrically coupled to a second metal trace within the second inner metal layer that is electrically coupled to another power or ground net. According to yet another aspect, the first via coupling component is an extension pad, the extension pad electrically coupled to a first surface of the electrode, the extension pad including at least one of a first overhang region that extends beyond a first edge of the electrode and/or a second overhang region that extends beyond a first widthwise edge of the electrode.

According to one aspect, the plurality of vias each have a second end that is electrically coupled to a first outer metal layer, a first portion of the extension pad extending beyond the first edge of the electrode, and at least a second portion of the extension pad is positioned within a first inner metal layer, the first inner metal layer closer to the insulator layer than the first outer metal layer. According to another aspect, the extension pad is planar. According to yet another aspect, the extension pad has at least one of a wider width than the electrode or a longer length than the electrode. According to yet another aspect, the extension pad includes both the first overhang region that extends beyond the first edge of the electrode and the second overhang region that extends beyond the first widthwise edge of the electrode, the first widthwise edge perpendicular to the first edge, and the extension pad further includes a third overhang region that extends beyond a second widthwise edge of the electrode, the second widthwise edge positioned on an opposite side of the first widthwise edge of the electrode.

According to one aspect, the first ends of the plurality of vias are electrically coupled to a first surface of the extension pad, and the at least first via of the plurality of vias is coupled to at least one of the first overhang region and/or the second overhang region. According to another aspect, a second surface of the extension pad is coupled to a first surface of a side plating, the side plating comprised of a metal, and a second surface of the side plating is coupled to a second surface of the electrode, the first surface of the side plating orthogonal to the second surface of the side plating, the first surface of the electrode orthogonal to the second surface of the electrode. According to yet another aspect, the DCC is a multi-layer chip capacitor.

According to one aspect, the first via coupling component reduces an inductance between the electrode and an integrated circuit die of the integrated circuit package. According to another aspect, the first via coupling component is a side plating having a first surface and a second surface, the electrode having a first surface and a second surface, the at least first via of the plurality of vias coupled to the first surface of the side plating, the second surface of the side plating electrically coupled to the second surface of the electrode, and at least a second via of the plurality of vias coupled to the first surface of the electrode. According to yet another aspect, the first surface and the second surface of the electrode are orthogonal to each other, and the first surface and the second surface of the side plating are orthogonal to each other. According to yet another aspect, the side plating is a metal alloy that comprises at least tin.

Another feature provides a method of manufacturing a multi-layer package substrate of an integrated circuit package, where the method comprises providing an insulator layer, and a discrete circuit component (DCC) having at least one electrode, embedding the DCC at least partially within the insulator layer, providing a first via coupling component, and a plurality of vias each having a first end, electrically coupling the first via coupling component to the electrode, extending a first portion of the first via coupling component beyond a first edge of the electrode, coupling the first end of each of the plurality of vias to the first via coupling component, and coupling at least a first via of the plurality of vias to the first portion of the first via coupling component that extends beyond the first edge of the electrode. According to one aspect, the method further comprises increasing an available surface area to which the first ends of the plurality of vias couple to using the first via coupling component. According to another aspect, the method further comprises providing a first outer metal layer and a first inner metal layer, electrically coupling a second end of each of the plurality of vias to the first outer metal layer, and positioning at least a second portion of the first via coupling component within the first inner metal layer, wherein the first inner metal layer is closer to the insulator layer than the first outer metal layer. According to yet another aspect, the method further comprises providing a first metal trace within the first inner metal layer, electrically coupling the first via coupling component to the first metal trace, and electrically coupling the first metal trace to a power or ground net.

According to one aspect, the method further comprises providing a second via coupling component, electrically coupling the second via coupling component to the electrode, extending a first portion of the second via coupling component beyond a second edge of the electrode, providing a second inner metal layer and a second metal trace within the second inner metal layer, positioning at least a second portion of the second via coupling component within the second inner metal layer, electrically coupling the second via coupling component to the second metal trace, and electrically coupling the second metal trace to another power or ground net. According to another aspect, the first via coupling component is an extension pad, and the method further comprises electrically coupling the extension pad to a first surface of the electrode, the extension pad including at least one of a first overhang region that extends beyond a first edge of the electrode and/or a second overhang region that extends beyond a first widthwise edge of the electrode. According to yet another aspect, the method further comprises providing a first outer metal layer and a first inner metal layer, electrically coupling a second end of each of the plurality of vias to the first outer metal layer, extending a first portion of the extension pad beyond the first edge of the electrode, and positioning at least a second portion of the extension pad within the first inner metal layer, the first inner metal layer closer to the insulator layer than the first outer metal layer.

According to one aspect, the extension pad includes both the first overhang region that extends beyond the first edge of the electrode and the second overhang region that extends beyond the first widthwise edge of the electrode, the first widthwise edge perpendicular to the first edge, and the extension pad further includes a third overhang region that extends beyond a second widthwise edge of the electrode, the second widthwise edge positioned on an opposite side of the first widthwise edge of the electrode. According to another aspect, the method further comprises electrically coupling the first ends of the plurality of vias to a first surface of the extension pad, and coupling the at least first via of the plurality of vias to at least one of the first overhang region and/or the second overhang region. According to yet another aspect, the method further comprises providing a side plating, coupling a second surface of the extension pad to a first surface of the side plating, the side plating comprised of a metal, and coupling a second surface of the side plating to a second surface of the electrode, the first surface of the side plating orthogonal to the second surface of the side plating, the first surface of the electrode orthogonal to the second surface of the electrode.

According to one aspect, the DCC is a capacitor, and the first via coupling component reduces an inductance between the electrode and an integrated circuit die of the integrated circuit package. According to another aspect, the first via coupling component is a side plating having a first surface and a second surface, the electrode having a first surface and a second surface, and the method further comprises coupling the at least first via of the plurality of vias to the first surface of the side plating, electrically coupling the second surface of the side plating to the second surface of the electrode, and coupling at least a second via of the plurality of vias to the first surface of the electrode. According to yet another aspect, the first surface and the second surface of the electrode are orthogonal to each other, and the first surface and the second surface of the side plating are orthogonal to each other.

Another feature provides a multi-layer package substrate of an integrated circuit package that comprises a means for insulating, a discrete circuit component (DCC) having at least one electrode, the DCC embedded at least partially within the means for insulating, a first means for increasing surface area electrically coupled to the electrode, a first portion of the first means for increasing surface area extending beyond a first edge of the electrode, and a plurality of vias each having a first end coupled to the first means for increasing surface area, at least a first via of the plurality of vias coupled to the first portion of the first means for increasing surface area extending beyond the first edge of the electrode. According to one aspect, the first means for increasing surface area increases an available surface area to which the first ends of the plurality of vias are coupled to. According to another aspect, the plurality of vias each have a second end that are electrically coupled to a first outer metal layer, and at least a second portion of the first means for increasing surface area is positioned within a first inner metal layer, wherein the first inner metal layer is closer to the means for insulating than the first outer metal layer. According to yet another aspect, the first via coupling component is electrically coupled to a first metal trace within the first inner metal layer that is electrically coupled to a power or ground net. According to another aspect, the package substrate further comprises a second means for increasing surface area that is electrically coupled to the electrode, a first portion of the second means for increasing surface area extending beyond a second edge of the electrode, at least a second portion of the second means for increasing surface area positioned within a second inner metal layer, the second means for increasing surface area electrically coupled to a second metal trace within the second inner metal layer that is electrically coupled to another power or ground net.

### BRIEF DESCRIPTION OF THE DRAWINGS

FIG. 1 illustrates a cross-sectional, schematic view of an IC package found in the prior art.

FIG. 2 illustrates a cross-sectional, schematic view of a portion of the package substrate found in the prior art.

FIG. 3 illustrates a perspective, schematic view of a capacitor coupled to vias found in the prior art.

FIG. 4 illustrates a cross-sectional, schematic view of an IC package.

FIG. 5 illustrates a schematic, cross-sectional view of a portion of a package substrate.

FIGS. 6 and 7 illustrate perspective, schematic views of a discrete circuit component (DCC), extension pads on a top side of the DCC, and vias that electrically couple the extension pads to a first outer metal layer.

FIG. 8 illustrates a schematic, cross-sectional view of a portion of a package substrate.

FIG. 9 illustrates a schematic, cross-sectional view of a portion of a package substrate that better illustrates how side platings couple to electrodes.

FIG. 10 illustrates a schematic, cross-sectional view of a portion of a package substrate.

FIG. 11 illustrates a schematic, cross-sectional view of a portion of a package substrate where side platings and extension pads couple to electrodes.

FIGS. 12-21 generally illustrate a process for manufacturing package substrates.

FIG. 22 illustrates a flowchart for a method of manufacturing a multi-layer package substrate of an integrated circuit package.

FIG. 23 illustrates various electronic devices that may include an integrated circuit that features a package substrate.

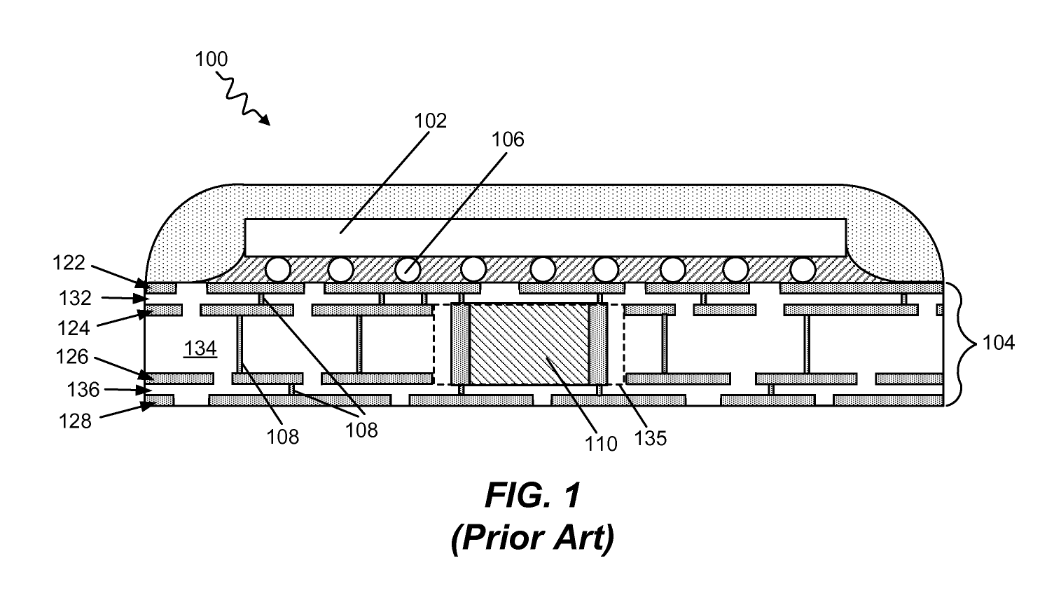

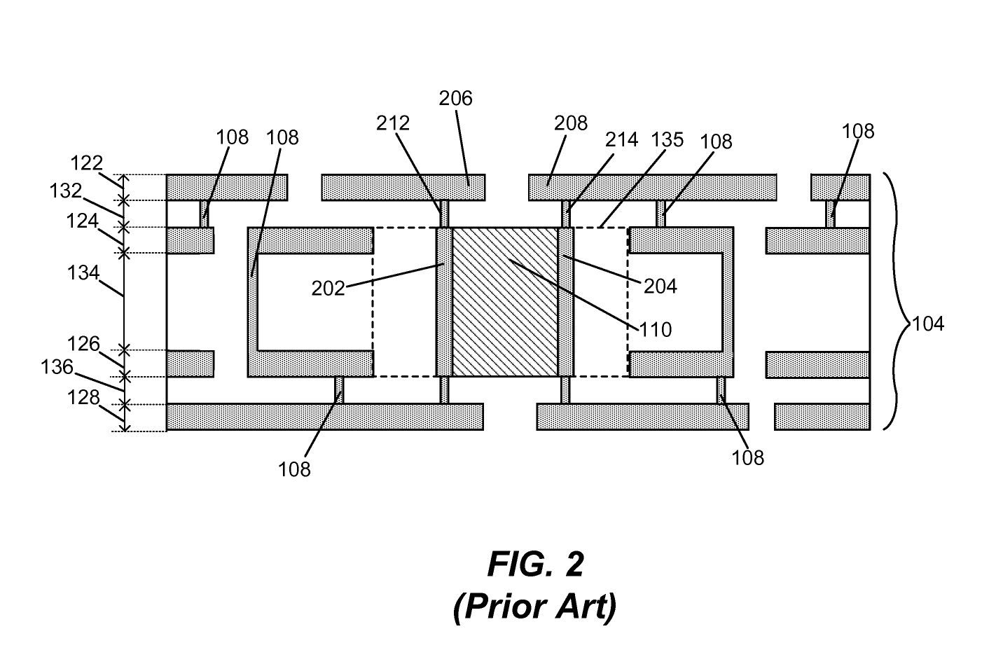

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. As used herein, the term “electrically coupled” is used herein to refer to the direct or indirect coupling between two objects that allows for the flow of electrical current to take place between the two objects. For example, if object A physically touches object B, and object B physically touches object C, then objects A and C may still be considered electrically coupled to one another—even if they do not directly physically touch each other—if object B is a conductor that allows for the flow of electrical current to take place from object A to object C and/or from object C to object A.

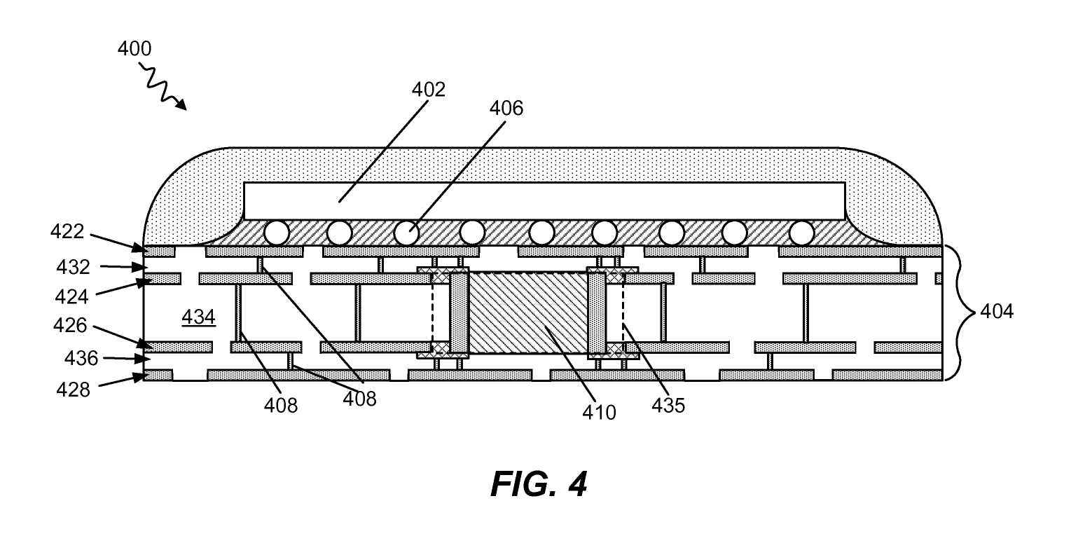

FIG. 4 illustrates a cross-sectional, schematic view of an IC package 400 according to one aspect of the disclosure. The IC package 400 includes an IC die 402 (e.g., memory circuit, processing circuit, applications processor, etc.) for an electronic device, such as, but not limited to, a mobile phone, laptop computer, tablet computer, personal computer, etc. The IC package 400, and in particular, the IC die 402 may be supplied power (e.g., provided nominal supply voltages and currents) from a power management integrated circuit (PMIC) (not shown) through a power delivery network (PDN) associated with the electronic device (portions of the PDN external to the IC package 400 are not shown).

The IC die 402 may be electrically coupled to a multi-layer package substrate 404 below it in a flip-chip style. For example, one or more soldering balls 406 may electrically couple the die 402 to metal traces located within a first metal layer 422 of the package substrate 404. According to other aspects, the IC die 402 may be wire bonded to the package substrate 404. The package substrate 404 may be, for example, a four metal layer laminate substrate. In other aspects, the package substrate 404 may have three or more metal layers, including five, six, seven, eight, nine, or ten metal layers.

The four layer package substrate 404 shown includes the first metal layer 422 (e.g., first outer metal layer), a second metal layer 424 (e.g., first inner metal layer), a third metal layer 426 (e.g., second inner metal layer), and a fourth metal layer 428 (e.g., second outer metal layer. Each of the metal layers 422, 424, 426, 428 are generally separated from one another by a plurality of insulating layers 432, 434, 436 that may be composed of one or more dielectric materials, such as, but not limited to, epoxy and/or resin. In particular, the first insulating layer 434 (e.g., core) in the middle of the package substrate 404 may be thicker than the other layers and also provides structural rigidity to the package substrate 404. A plurality of metal vertical interconnect accesses (vias) 408 electrically couple traces of the plurality of metal layers 422, 424, 426, 428 of the package substrate 404 to each other where desired.

The package substrate 404 includes a cavity 435 (indicated by the dashed line box) that houses an embedded passive substrate (EPS) discrete circuit component (DCC) 410, such as a capacitor, resistor, or inductor. The cavity 435 may occupy or be located within a portion of the first insulator layer 434, and also one or more of the inner metal layers 424, 426. In the illustrated example, the DCC 410 may be, for example, a discrete capacitor (e.g., “decoupling capacitor”) such as a multi-layer chip capacitor (MLCC). According to one aspect, the discrete capacitor 410 helps reduce the impedance at a range of frequencies of the PDN by balancing inductive components of the impedance due to the IC package 400 (e.g., inductance caused by traces, vias, metal lines, etc. associated with the package substrate 404). The package substrate 404 may have a plurality of cavities each housing a separate EPS DCC.

Among other things, the package substrate 404 may comprise one or more via coupling components that are electrically coupled to electrodes of the DCC 410. The via coupling components serve as a means for increasing the available surface area to which a plurality of vias may couple to (e.g., a first end of each via may couple to the via coupling components). The via coupling components are composed of a conductive material, such as a metal or metal alloy (e.g., copper, aluminum, and/or titanium nitride, etc.). According to one aspect, the via coupling components are made of one or more of the same metals that comprise the inner metal layers 424, 426.

According to one aspect, a first via coupling component is electrically coupled to both a first electrode of the DCC 410 and a first metal trace within the first inner metal layer 424; a second via coupling component is electrically coupled to both the first electrode and a second metal trace within the second inner metal layer 426; a third via coupling component is electrically coupled to both a second electrode of the DCC 410 and a third metal trace within the first inner metal layer 424; a fourth via coupling component is electrically coupled to both the second electrode and a fourth metal trace within the second inner metal layer 426.

Each of the aforementioned metal traces may be electrically coupled to a power or ground net associated with the package substrate 404. For example, the first metal trace may be electrically coupled to the second metal trace by means of a via, and the third metal trace may be electrically coupled to the fourth metal trace by means of another via. The via coupling components may be electrically coupled to power or ground nets within the first and second inner metal layers 424, 426, wherein the first and second inner metal layers are closer to the first insulator layer 434 than the outer metal layers 422, 428.

According to one aspect, a first portion of the first via coupling component extends beyond a first edge of the first electrode of the DCC 410. According to another aspect, a second portion of the first via coupling component is positioned within the first inner metal layer 424. Similarly, a first portion of the second via coupling component may extend beyond a second edge of the first electrode, and a second portion of the second via coupling component may be positioned within the second inner metal layer 426. According to one aspect, a first portion of the third via coupling component extends beyond a first edge of the second electrode of the DCC 410. According to another aspect, a second portion of the third via coupling component is positioned within the first inner metal layer 424. Similarly, a first portion of the fourth via coupling component may extend beyond a second edge of the second electrode, and a second portion of the fourth via coupling component may be positioned within the second inner metal layer 426.

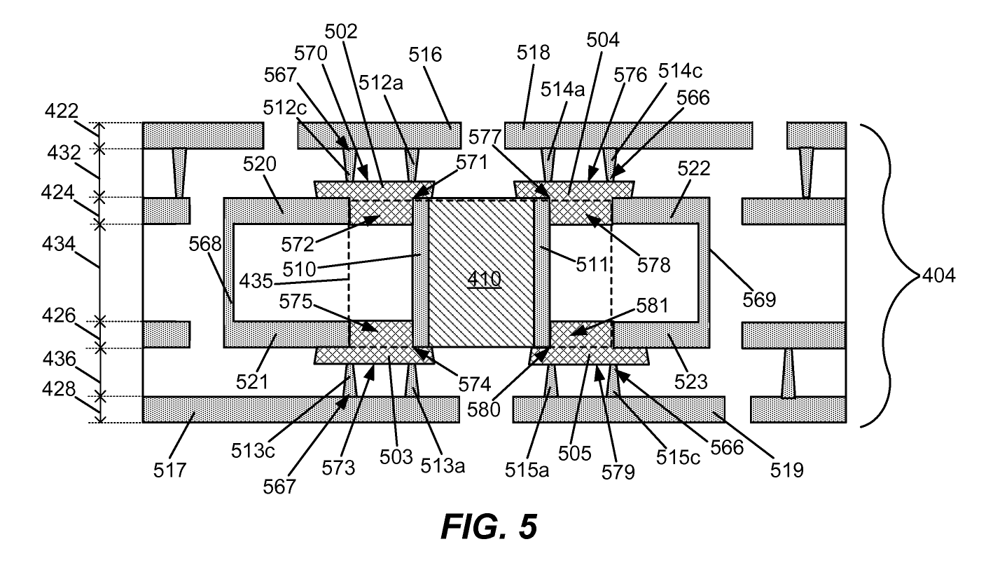

According to one aspect of the present disclosure, the via coupling components described above may be the extension pads 502, 503, 504, 505 shown in FIGS. 5-7.

FIG. 5 illustrates a schematic, cross-sectional view of a portion of the package substrate 404 according to one aspect. The extension pads 502, 503, 504, 505 are electrically coupled to the electrodes 510, 511 of the DCC 410. The extension pads 502, 503, 504, 505 serve as a means for increasing the available surface area to which a plurality of vias 512a, 512c, 513a, 513c, 514a, 514c, 515a, 515c may couple to (e.g., a first end 566 of each via 512a, 512c, 513a, 513c, 514a, 514c, 515a, 515c may couple to the extension pads 502, 503, 504, 505). The extension pads 502, 503, 504, 505 are composed of a conductive material, such as a metal or metal alloy (e.g., copper, aluminum, and/or titanium nitride, etc.). According to one aspect, the extension pads 502, 503, 504, 505 are made of one or more of the same metals that comprise the inner metal layers 424, 426. According to another aspect, the extension pads 502, 503, 504, 505 may be substantially planar.

According to one aspect, a first extension pad 502 is electrically coupled to both a first electrode 510 and a first metal trace 520 within the first inner metal layer 424; a second extension pad 503 is electrically coupled to both the first electrode 510 and a second metal trace 521 within the second inner metal layer 426; a third extension pad 504 is electrically coupled to both a second electrode 511 and a third metal trace 522 within the first inner metal layer 424; a fourth extension pad 505 is electrically coupled to both the second electrode 511 and a fourth metal trace 523 within the second inner metal layer 426.

Each metal trace 520, 521, 522, 523 may be electrically coupled to a power or ground net associated with the package substrate 404. In the illustrated example, the first metal trace 520 is electrically coupled to the second metal trace 521 by means of a via 568, and the third metal trace 522 is electrically coupled to the fourth metal trace 523 by means of another via 569. The extension pads 502, 503, 504, 505 may be electrically coupled to power or ground nets within the first and second inner metal layers 424, 426, where the first and second inner metal layers are closer to the first insulator layer 434 than the outer metal layers 422, 428.

According to one aspect, a first portion 570 of the first extension pad 502 extends beyond a first edge 571 of the first electrode 510. According to another aspect, a second portion 572 of the first extension pad 502 is positioned within the first inner metal layer 424. Similarly, a first portion 573 of the second extension pad 503 may extend beyond a second edge 574 of the first electrode 510, and a second portion 575 of the second extension pad 503 may be positioned within the second inner metal layer 426. According to one aspect, a first portion 576 of the third extension pad 504 extends beyond a first edge 577 of the second electrode 511. According to another aspect, a second portion 578 of the third extension pad 504 is positioned within the first inner metal layer 424. Similarly, a first portion 579 of the fourth extension pad 505 may extend beyond a second edge 580 of the second electrode 511, and a second portion 581 of the fourth extension pad 505 may be positioned within the second inner metal layer 426.

The extension pads 502, 503, 504, 505 electrically couple a plurality of vias 512a, 512c, 513a, 513c, 514a, 514c, 515a, 515c to the DCC 410. In the illustrated example, the DCC 410 may not directly couple to the vias 512a, 512c, 513a, 513c, 514a, 514c, 515a, 515c. Instead, the extension pads 502, 503, 504, 505 are positioned in between the DCC 410 and the vias 512a, 512c, 513a, 513c, 514a, 514c, 515a, 515c. Each via 512a, 512c, 513a, 513c, 514a, 514c, 515a, 515c has a first end 566 and a second, opposite end 567. (Note that for clarity not all ends 566, 567 of the vias 512a, 512c, 513a, 513c, 514a, 514c, 515a, 515c shown in FIGS. 5, 8, and 10 have been labeled.) The first end 566 of the vias 512a, 512c, 513a, 513c, 514a, 514c, 515a, 515c are coupled to the extension pads 502, 503, 504, 505. Moreover, the second end 567 (opposite the first end 566) of the vias 512a, 512c, 513a, 513c, 514a, 514c, 515a, 515c are electrically coupled to the outer metal layers 422, 428. For example, a second end 567 of the vias 512a, 512c are electrically coupled to a trace 516 within the first outer metal layer 422; a second end 567 of the vias 513a, 513c are electrically coupled to a trace 517 within the second outer metal layer 428; a second end 567 of the vias 514a, 514c are electrically coupled to a trace 518 within the first outer metal layer 422; a second end 567 of the vias 515a, 515c are electrically coupled to a trace 519 within the second outer metal layer 428.

According to one aspect, one or more of the traces 516, 517, 518, 519 may be electrically coupled to power or ground nets within the outer metal layers 422, 428 associated with the package substrate 404. As described above, the metal traces 520, 521, 522, 523 may be electrically coupled to power or ground nets within the inner metal layers 424, 426. Since the DCC's electrodes 510, 511 are electrically coupled to one or more of the traces 516, 517, 518, 519, 520, 521, 522, 523 through the extension pads 502, 503, 504, 505 and/or the vias 512a, 512c, 513a, 513c, 514a, 514c, 515a, 515c, the DCC 410 may be electrically coupled to power and/or ground nets within all of the metal layers of the package substrate 404, including the outer metal layers 422, 428 and the inner metal layers 424, 426.

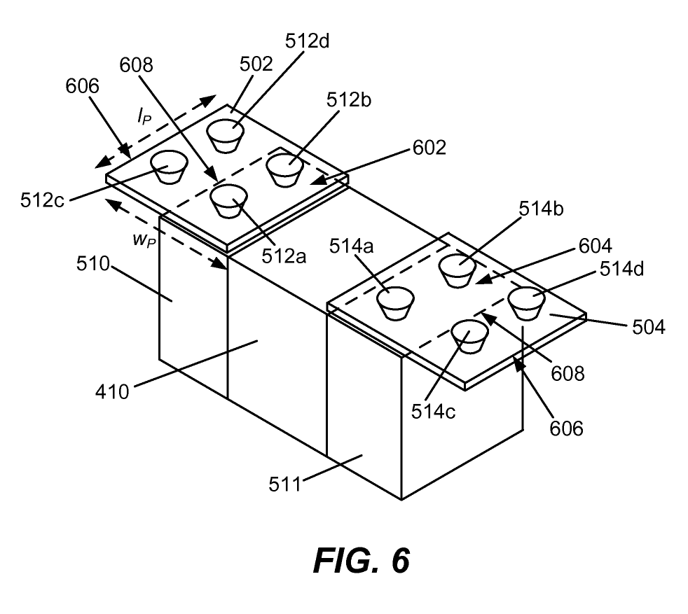

FIG. 6 illustrates a perspective, schematic view of the DCC 410, the extension pads 502, 504 on the top side of the DCC 410, and the vias that electrically couple the extension pads 502, 504 to the first outer metal layer 422 according to one aspect. (Note that for clarity, extension pads 503, 505 on the bottom side of the DCC 410 have been omitted from FIG. 6.) As shown, the DCC 410 includes the first and second metal electrodes 510, 511. For example, each end of the DCC 410 may be coated with a metal to form the electrodes 510, 511.

Top surfaces (e.g., first surfaces) of the electrodes 510, 511 may be electrically coupled to bottom surfaces (e.g., second surfaces) of the extension pads 502, 504. A top surface 602 (e.g., first surface) of the first extension pad 502 may be electrically coupled to a plurality of vias (e.g., four vias) 512a, 512b, 512c, 512d, and a top surface 604 of the third extension pad 504 may be electrically coupled to a plurality of vias (e.g., four vias) 514a, 514b, 514c, 514d. Referring to FIGS. 5 and 6, the vias 512a, 512b, 512c, 512d electrically couple the first electrode 510 to the trace 516 of the first outer metal layer 422, and the vias 514a, 514b, 514c, 514d electrically couple the second electrode 511 to the trace 518 of the first outer metal layer 422.

Referring to FIG. 6, each extension pad 502, 504 may have a width w_{P} and a length l_{P}. According to one aspect, the widths w_{P} of the extension pads 502, 504 are greater than the widths w_{E} of the electrodes 510, 511. According to one aspect, the widths w_{P} of the extension pads 502, 504 are equal to or less than the widths w_{E} of the electrodes 510, 511. In the illustrated example, the widths w_{P} of the extension pads 502, 504 are greater than the widths w_{E} of the electrodes 510, 511, and the lengths l_{P} of the extension pads 502, 504 are substantially equal to the lengths l_{E} of the electrodes 510, 511. The extension pads 502, 504 may each include a first overhang region 606 that extends beyond a lengthwise edge 608 (e.g., first edge) of the DCC's electrodes 510, 511. The first overhang regions 606 allow one or more vias 512c, 512d, 514c, 514d to electrically couple to the extension pads 502, 504 beyond the lengthwise edges 608 of the electrodes 510, 511.

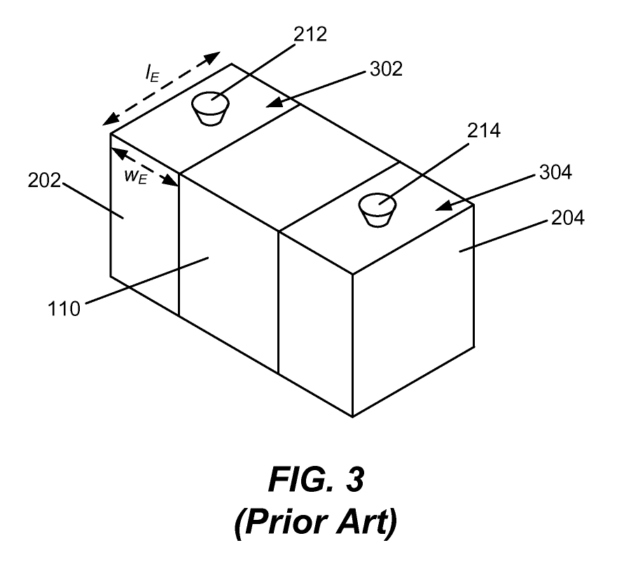

The larger widths w_{P} of the extension pads 502, 504 compared to the electrode widths w_{E} may provide a larger top surface 602, 604 area than the top surfaces of the electrodes 510, 511 underneath. This allows for a greater number of vias 512a, 512b, 512c, 512d, 514a, 514b, 514c, 514d to be electrically coupled to the DCC 410 than if the extension pads 502, 504 were absent (e.g., see FIG. 3 where a limited number of vias 212, 214 directly couple to the electrodes 202, 204). Having a greater number of vias (e.g., four in the example shown in FIG. 6) electrically couple to each extension pad 502, 504 and in turn to each electrode 510, 511, reduces the inductance L_{Trace} and/or the resistance R_{Trace} If there are extension pads 503, 505 electrically coupled to the bottom surfaces of the electrodes 510, 511 as well (as shown in FIG. 5), then the total number of vias electrically coupled to each electrode 510, 511 may be eight (four on top, and four on bottom). The reduced inductance and/or resistance reduces the impedance of the PDN at a certain frequency range which decreases power consumption and increases efficiency.

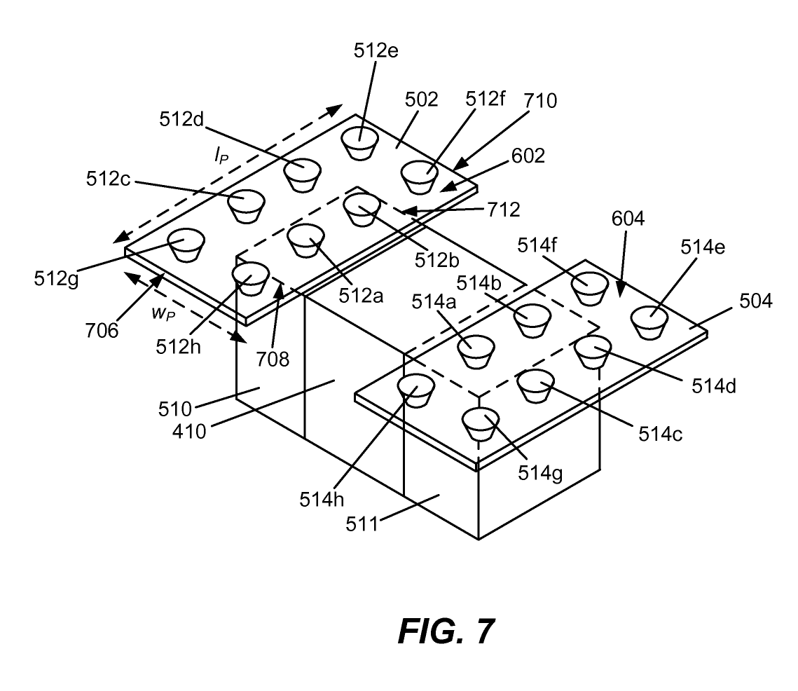

FIG. 7 illustrates a perspective, schematic view of the DCC 410, the extension pads 502, 504 on top side of the DCC 410, and the vias that electrically couple the DCC 410 to the first outer metal layer 422 according to another aspect. (Note that for clarity, extension pads 503, 505 that may be located on the bottom side of the DCC 410 have been omitted from FIG. 7.) In the example shown, the top surface 702 (e.g., first surface) of the first extension pad 502 may be electrically coupled to a plurality of vias (e.g., eight vias) 512a, 512b, 512c, 512d, 512e, 512f, 512g, 512h, and a top surface 704 of the third extension pad 504 may be electrically coupled to a plurality of vias (e.g., eight vias) 514a, 514b, 514c, 514d, 514e, 514f, 514g, 514h. Referring to FIGS. 5 and 7, the vias 512a, 512b, 512c, 512d, 512e, 512f, 512g, 512h electrically couple the first electrode 510 to the trace 516 of the first outer metal layer 422, and the vias 514a, 514b, 514c, 514d, 514e, 514f, 514g, 514h electrically couple the second electrode 511 to the trace 518 of the first outer metal layer 422.

Referring to FIG. 7, each extension pad 502, 504 may have a width w_{P} and a length l_{P}. According to one aspect, the lengths l_{P} of the extension pads 502, 504 are greater than the lengths l_{E} of the electrodes 510, 511. According to one aspect, the lengths l_{P} of the extension pads 502, 504 are equal to or less than the lengths l_{E} of the electrodes 510, 511. In the illustrated example, the widths w_{P} and lengths l_{P} of the extension pads 502, 504 are greater than the widths w_{E} and lengths l_{P} of the electrodes 510, 511, respectively. The extension pads 502, 504 may each include a second overhang region 706 that extends beyond a first widthwise edge 708 of the DCC's electrodes 510, 511. The second overhang regions 706 allow one or more vias 512g, 512h, 514g, 514h to electrically couple to the extension pads 502, 504 beyond the first widthwise edges 708 of the electrodes 510, 511. The extension pads 502, 504 may also each include a third overhang region 710 that extends beyond a second widthwise edge 712 of the discrete circuit component's electrodes 510, 511. The third overhang regions 710 allow one or more vias 512e, 512f, 514e, 514f to electrically couple to the extension pads 502, 504 and the electrodes 510, 511 beyond the second widthwise edges 712 of the electrodes 510, 511.

The larger lengths l_{P} of the extension pads 502, 504 compared to the electrode widths l_{E} may provide a larger top surface 702, 704 area than the top surfaces of the electrodes 510, 511 underneath. This allows a greater number of vias 512a, 512b, 512c, 512d, 512e, 512f, 512g, 512h, 514a, 514b, 514c, 514d, 514e, 514f, 514g, 514h to be electrically coupled to the DCC 410 than if the extension pads 502, 504 were absent (e.g., see FIG. 3 where a limited number of vias 212, 214 directly couple to the electrodes 202, 204). Having a greater number of vias (e.g., eight in the example shown in FIG. 7) electrically couple to each extension pad 502, 504 and each electrode 510, 511 in turn, reduces the inductance L_{Trace} and/or the resistance R_{Trace}. If there are extension pads electrically coupled to the bottom surfaces of the electrodes 510, 511 as well (as shown in FIG. 5), then the total number of vias electrically coupled to each electrode 510, 511 may be sixteen (eight on top, and eight on bottom). The reduced inductance and/or resistance reduces the impedance of the PDN at a certain frequency range which decreases power consumption and increases efficiency.

The size (e.g., lengths l_{P} and widths w_{P}) of the extension pads 502, 504 and the number of vias electrically coupled thereto shown in FIGS. 6 and 7 are merely examples. In practice, any number of vias may be electrically coupled to the extension pads 502, 504. For example, each extension pad 502, 504 may also be coupled to two, three, five, six, seven, nine, or more vias, with any number of the vias electrically coupled to the first, second, and/or third overhang regions 606, 706, 710.

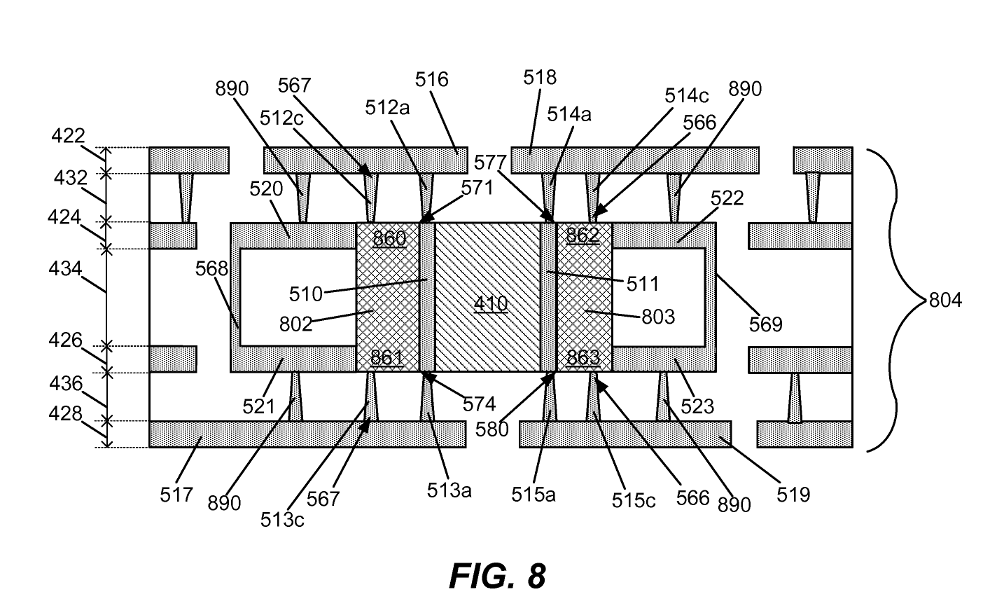

According to another aspect of the present disclosure, the via coupling components described above may be the side platings 802, 803 shown in FIGS. 8 and 9.

FIG. 8 illustrates a schematic, cross-sectional view of a portion of a package substrate 804 according to one aspect of the disclosure. The package substrate 804 features side platings 802, 803 that occupy portions of the cavity 435 instead of the extension pads 502, 503, 504, 505. The side platings 802, 803 are electrically coupled to the electrodes 510, 511 of the DCC 410. The side platings 802, 803 serve as a means for increasing the available surface area to which a plurality of vias 512a, 512c, 513a, 513c, 514a, 514c, 515a, 515c may couple to (e.g., a first end 566 of each via 512a, 512c, 514a, 514c, 513a, 513c, 515a, 515c may couple to the side platings 802, 803). In the illustrated example, however, the vias 512c, 513c, 514c, 515c are electrically coupled to the side platings 802, 803, while the vias 512a, 513a, 514a, 515a are electrically coupled to the electrodes 510, 511. The side platings 802, 803 are composed of a conductive material, such as a metal or metal alloy (e.g., copper, aluminum, tin, and/or titanium nitride, etc.). According to one aspect, the side platings 802, 803 are made of one or more of the same metals that comprise the inner metal layers 424, 426. The side platings 802, 803 provide increased structural rigidity and/or stability to the package substrate 804 since the side platings 802, 803 fill in portions of the cavity 435 (cavity shown in FIG. 5) along the sides of the electrodes 510, 511 that may otherwise be filled with a less rigid material such as epoxy resin.

According to one aspect, a first side plating 802 is electrically coupled to the first electrode 510, the first metal trace 520 within the first inner metal layer 424, and the second metal trace 521 within the second inner metal layer 426. The second side plating 803 may be electrically coupled to the second electrode 511, the third metal trace 522 within the first inner metal layer 424, and the fourth metal trace 523 within the second inner metal layer 426.

Each metal trace 520, 521, 522, 523 may be electrically coupled to a power or ground net associated with the package substrate 804. In the illustrated example, the first metal trace 520 is electrically coupled to the second metal trace 521 by means of a via 568, and the third metal trace 522 is electrically coupled to the fourth metal trace 523 by means of another via 569. In this fashion, the side platings 802, 803 may be electrically coupled to power or ground nets within the first and second inner metal layers 424, 426, wherein the first and second inner metal layers are closer to the first insulator layer 434 than the outer metal layers 422, 428. According to one aspect, additional vias 890 may couple to the metal traces 520, 521, 522, 523 so that a greater number of total vias are electrically coupled to the electrodes 510, 511 (since the metal traces 520, 521, 522, 523 are electrically coupled to the side platings 802, 803, which are in turn electrically coupled to the electrodes 510, 511).

According to one aspect, a first portion 860 of the first side plating 802 extends beyond the first edge 571 of the first electrode 510, and the first portion 860 is positioned within the first inner metal layer 424. According to another aspect, a second portion 861 of the first side plating 802 extends beyond the second edge 574 of the first electrode 510, and the second portion 861 is positioned within the second inner metal layer 426. Similarly, according to one aspect a first portion 862 of the second side plating 803 extends beyond the first edge 577 of the second electrode 511, and the first portion 862 is positioned within the first inner metal layer 424. According to another aspect, a second portion 863 of the second side plating 803 extends beyond the second edge 580 of the second electrode 511, and the second portion 863 is positioned within the second inner metal layer 426.

FIG. 9 illustrates a schematic, cross-sectional view of a portion of the package substrate 804 that better illustrates how the side platings 802, 803 couple to the electrodes 510, 511. Referring to FIGS. 8 and 9, the side platings 802, 803 electrically couple a plurality of vias 512c, 513c, 514c, 515c to the DCC 410. Other vias 512a, 513a, 514a, 515a may directly couple to the electrodes 510, 511. Specifically, a first end 566 of the via 512c may couple to a first surface 902 (e.g., top surface) of the first side plating 802, and a first end 566 of the via 512a may couple to a first surface 904 (e.g., top surface) of the first electrode 510. A second end 567 of the vias 512a, 512c may couple to the metal trace 516 within the first outer metal layer 422. A second surface 906 (e.g., inner side surface) of the first side plating 802 may couple to a second surface 908 (e.g., outer side surface) of the first electrode 510, where the second surface 906 of the first side plating 802 is orthogonal to the first surface 902, and the second surface 908 of the first electrode 510 is orthogonal to the first surface 904. Similarly, a first end 566 of the via 513c may couple to a third surface 910 (e.g., bottom surface) of the first side plating 802, and a first end 566 of the via 513a may couple to a third surface 912 (e.g., bottom surface) of the first electrode 510. A second end 567 of the vias 513a, 513c may couple to the metal trace 517 within the second outer metal layer 428. Similar connections may be made between the second electrode 511, the second side plating 803, and the vias 514a, 514c, 515a, 515c.

According to one aspect, one or more of the traces 516, 517, 518, 519 may be electrically coupled to power or ground nets within the outer metal layers 422, 428 associated with the package substrate 804. As described above, the metal traces 520, 521, 522, 523 may be electrically coupled to power or ground nets within the inner metal layers 424, 426. Since the DCC's electrodes 510, 511 are electrically coupled to one or more of the traces 516, 517, 518, 519, 520, 521, 522, 523 through the side platings 802, 803 and/or the vias 512a, 512c, 513a, 513c, 514a, 514c, 515a, 515c, the DCC 410 may be electrically coupled to power and/or ground nets within all of the metal layers of the package substrate 804, including the outer metal layers 422, 428 and the inner metal layers 424, 426.

According to one aspect, any number of vias greater than two (e.g., three, four, six, eight, ten, etc.) may be coupled to each first surface 902 and third surface 910 of the side platings 802, 803. For example, the vias 512a, 512b, 512c, 512d, 512e, 512f, 512g, 512h, 514a, 514b, 514c, 514d, 514e, 514f, 514g, 514h shown in FIGS. 6 and/or 7 may couple to the first and third surfaces 902, 910 of the side platings 802, 803 in a similar fashion to that shown in FIGS. 6 and/or 7.

The first and third surfaces 902, 910 of the side platings 802, 803 provide increased surface area for a greater number of vias to electrically couple to the DCC 410 (indirectly through the side platings 802, 803) than if the side platings 802, 803 were absent (e.g., see FIG. 3 where a limited number of vias 212, 214 directly couple to the electrodes 202, 204). Having a greater number of vias (e.g., two or more) electrically couple to each surface 902, 910 of the side platings 802, 803, and in turn to each electrode 510, 511, reduces the inductance L_{Trace} and/or the resistance R_{Trace}. If the side platings 802, 803 are coupled to metal traces 520, 521, 522, 523, then more vias may couple to the metal traces 520, 521, 522, 523, and in turn electrically couple to the electrodes 510, 51 further reducing the inductance L_{Trace} and/or the resistance R_{Trace}. The reduced inductance and/or resistance reduces the impedance of the PDN at a certain frequency range which decreases power consumption and increases efficiency

Besides providing structural rigidity and/or stability, the side platings 802, 803 also reduce contact resistance between the electrodes 510, 511 and the vias 512c, 513c, 514c, 515c. For example, the DCC 410 may be an MLCC that comprises a plurality of layers that result in a plurality of individual electrodes. Physically and/or electrically coupling the aforementioned plurality of individual electrodes to the side metal plating 802, 803, helps decrease the contact resistance associated with the MLCC.

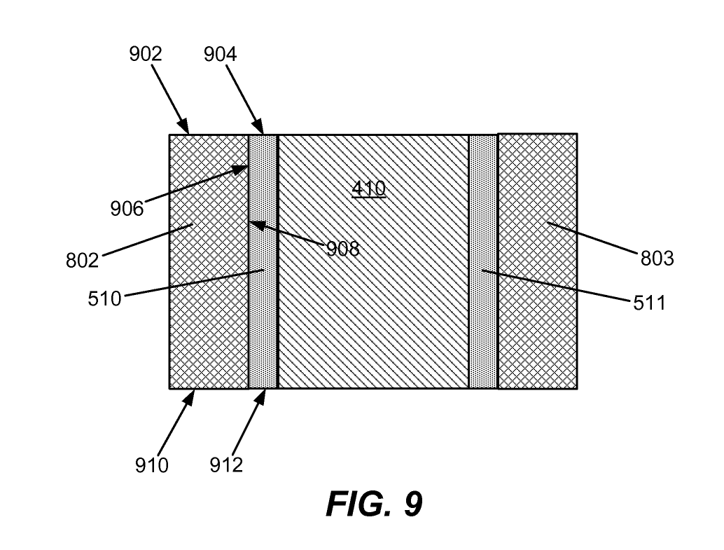

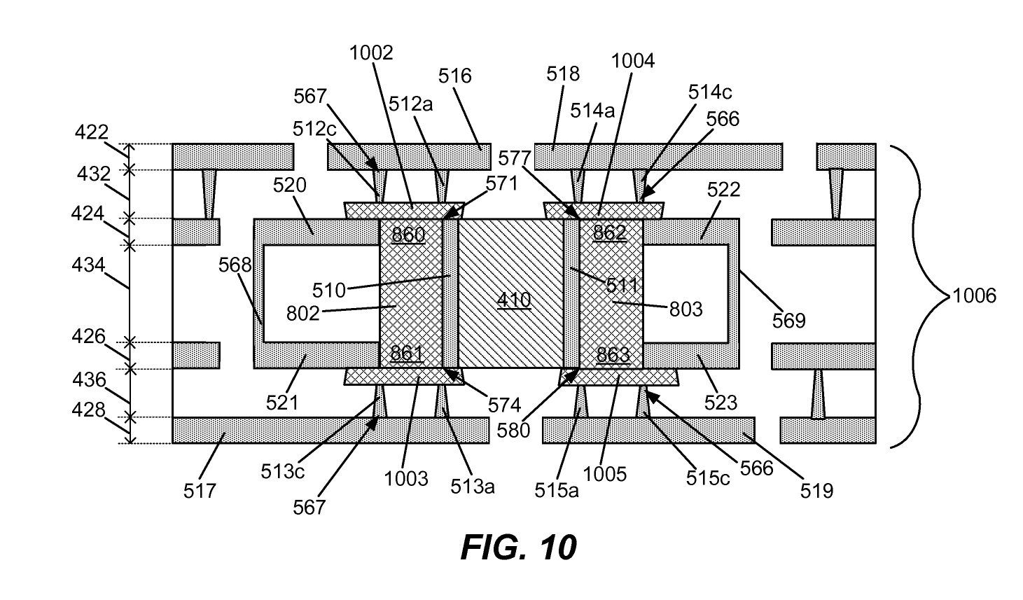

FIG. 10 illustrates a schematic, cross-sectional view of a portion of a package substrate 1006 according to one aspect. The package substrate 1006 represents a hybridization of the package substrate 404 shown in FIG. 5 and the package substrate 804 shown in FIG. 8. Specifically, the package substrate 1006 features both the extension pads 1002, 1003, 1004, 1005 and the side platings 802, 803 that electrically couple to the electrodes 510, 511 of the DCC 410. FIG. 11 illustrates a schematic, cross-sectional, detailed view of a portion of the package substrate 1006 where the side platings 802, 803, the extension pads 1002, 1003, 1004, 1005 couple to the electrodes 510, 511.

Referring to FIGS. 10 and 11, the first end 566 of the vias 512a, 512c couple to a first surface 1110 of the first extension pad 1002, and a second end 567 of the vias 512a, 512c electrically couple to the trace 516 within the first outer metal layer 422; the first end 566 of the vias 513a, 513c couple to a first surface 1111 of the second extension pad 1003, and a second end 567 of the vias 513a, 513c electrically couple to the trace 517 within the second outer metal layer 428; the first end 566 of the vias 514a, 514c couple to a first surface 1112 of the third extension pad 1004, and a second end 567 of the vias 514a, 514c electrically couple to the trace 518 within the first outer metal layer 422; and the first end 566 of the vias 515a, 515c couple to a first surface 1113 of the fourth extension pad 1005, and a second end 567 of the vias 515a, 515c electrically couple to the trace 519 within the second outer metal layer 428. Moreover, the first surface 902 of the first side plating 802 may couple to a second surface 1120 (opposite the first surface 1110) of the first extension pad 1002; the third surface 910 of the first side plating 802 may couple to a second surface 1121 (opposite the first surface 1111) of the second extension pad 1003; the first surface 1130 of the second side plating 803 may couple to a second surface 1122 (opposite the first surface 1112) of the third extension pad 1004; and the third surface 1132 of the second side plating 803 may couple to a second surface 1123 (opposite the first surface 1113) of the fourth extension pad 1005.

According to one aspect, any number of vias greater than two (e.g., three, four, six, eight, ten, etc.) may be coupled to each first surface 1110, 1111, 1112, 1113 of the extension pads 1002, 1003, 1004, 1005. For example, the vias 512a, 512b, 512c, 512d, 512e, 512f, 512g, 512h, 514a, 514b, 514c, 514d, 514e, 514f, 514g, 514h shown in FIGS. 6 and/or 7 may couple to the first surface 1110, 1111, 1112, 1113 of the extension pads 1002, 1003, 1004, 1005 in a similar fashion to that shown in FIGS. 6 and/or 7.

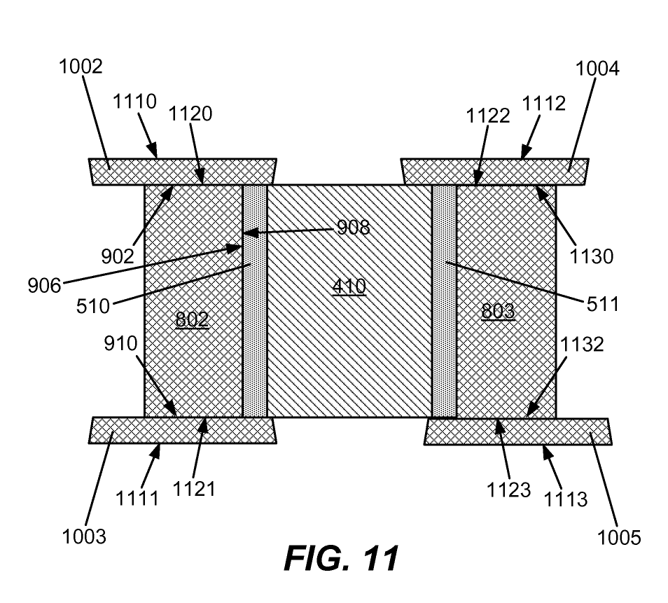

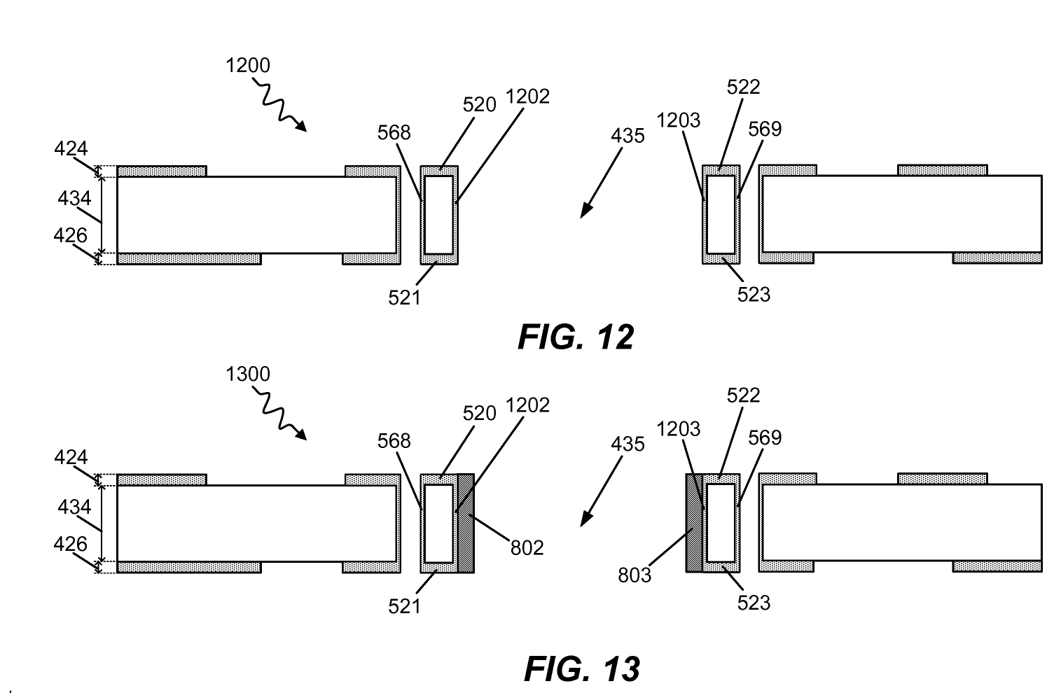

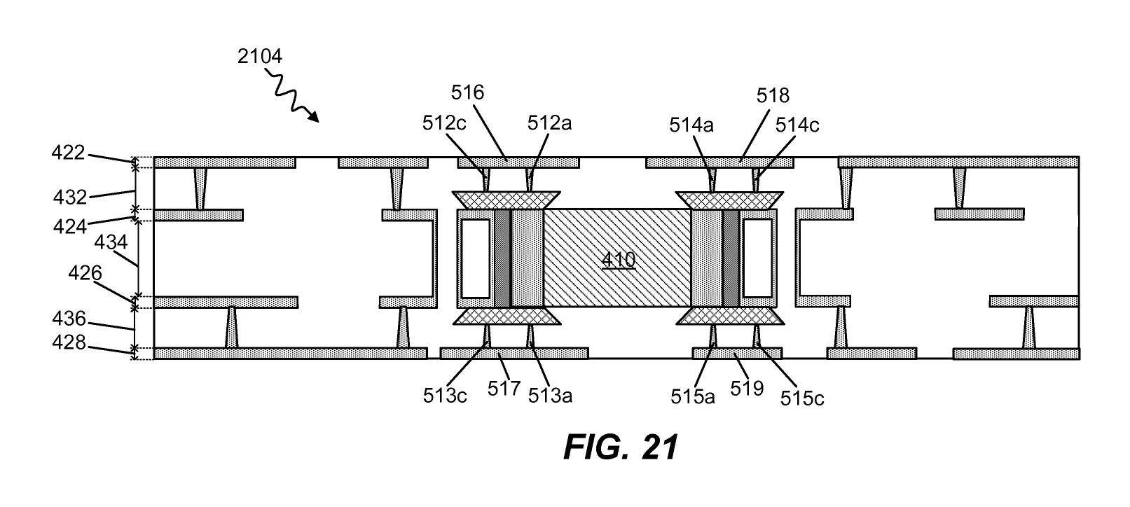

FIGS. 12-21 generally illustrate a process for manufacturing the package substrates 404, 804, 1006 described above according to one aspect. Although the process concludes with the assembly of a package substrate 2104 shown in FIG. 21, modifications to the process may yield the package substrates 404, 804, 1006 described above with the respect to FIGS. 4-11.

FIG. 12 illustrates the process in an intermediate manufacturing stage 1200 according to one aspect. As shown, the first insulator layer 434 (e.g., core) is provided having the first inner metal layer 424 on top and the second inner metal layer 426 on the bottom of the core 434. The core 434 may be comprised of a rigid dielectric, such as epoxy resin, and the inner metal layers 424, 426 may be comprised of copper, aluminum, etc. The core 434 and the inner metal layers 424, 426 may be comprised of different dielectrics and metals, respectively. A cavity 435 may be formed in the core 434 and inner metal layers 424, 426. The traces 520, 522 within the first inner metal layer 424, the traces 521, 523 within the second inner metal layer 426, and the vias 568, 569 may be formed using deposition, patterning, and/or removal (e.g., dry and/or wet etching, chemical mechanical planarization (CMP)) process steps. Such, deposition, patterning, and/or removal process steps may be herein referred to as DPR process steps. As shown in FIG. 12, the process 1200 may include forming the metal vias 1202, 1203 along the outer side walls of the cavity 435. According to one aspect, however, the vias 1202, 1203 may be absent so that portions of the first insulator layer 434 define the outer side walls of the cavity 435.

FIG. 13 illustrates the process in an intermediate manufacturing stage 1300 according to one aspect. One or more DPR process steps may be utilized to form the first and second side platings 802, 803 within the cavity 435. The side platings 802, 803 may be comprised of, but are not limited to, copper, aluminum, tin, lead, and/or other conductive materials. According to one aspect, the side platings 802, 803 may not be formed, for example, when manufacturing the package substrate 404 shown in FIG. 5.

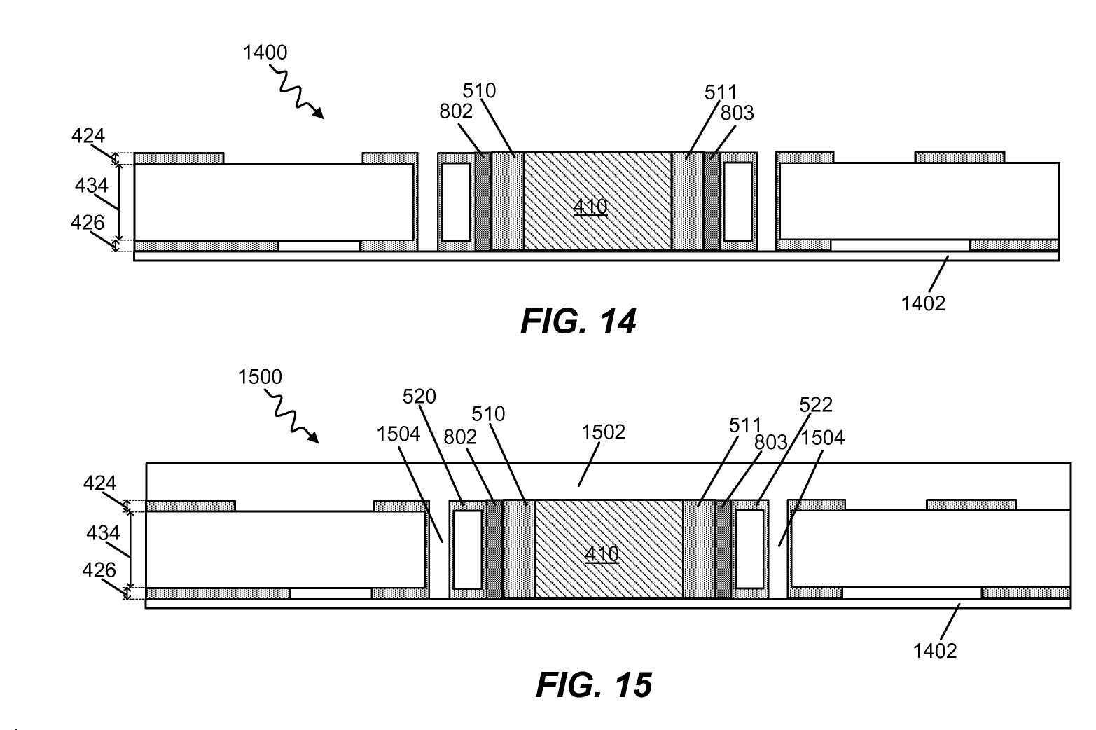

FIG. 14 illustrates the process in an intermediate manufacturing stage 1400 according to one aspect. As shown, the discrete circuit component 410 may be provided and placed within the cavity 435 (see FIG. 13 for cavity 435) on top of an adhesive tape 1402 that is applied to the second inner metal layer 426. The DCC 410 includes the first and second electrodes 510, 511. According to one aspect, the DCC 410 may be press fit into the cavity 435 so that the electrodes 510, 511 electrically couple to the first side plating 802 and the second side plating 803, respectively, by simple physical contact. According to another aspect, the DCC's electrode's 510, 511 may be soldered bonded to the side platings 802, 803. For example, the side platings 802, 803 may be comprised of at least in part tin (Sn) which may form a solder bond to the electrodes 510, 511 once raised to a certain temperature and then cooled. According to one aspect, if the side platings 802, 803 are absent, then the DCC 410 may simply be placed within the cavity 435 on top of the adhesive tape 1402. In that case, the spaces between the DCC 410 and the vias 1202, 1203 may be filled with an epoxy resin.

FIG. 15 illustrates the process in an intermediate manufacturing stage 1500 according to one aspect. As shown, a lamination step causes a dielectric material 1502, such as epoxy resin, to be deposited/formed and cured on top of the first inner metal layer 424, the DCC 410, the traces 520, 522, and the side platings 802, 803. The dielectric material 1502 may also permeate through the via holes 1504.

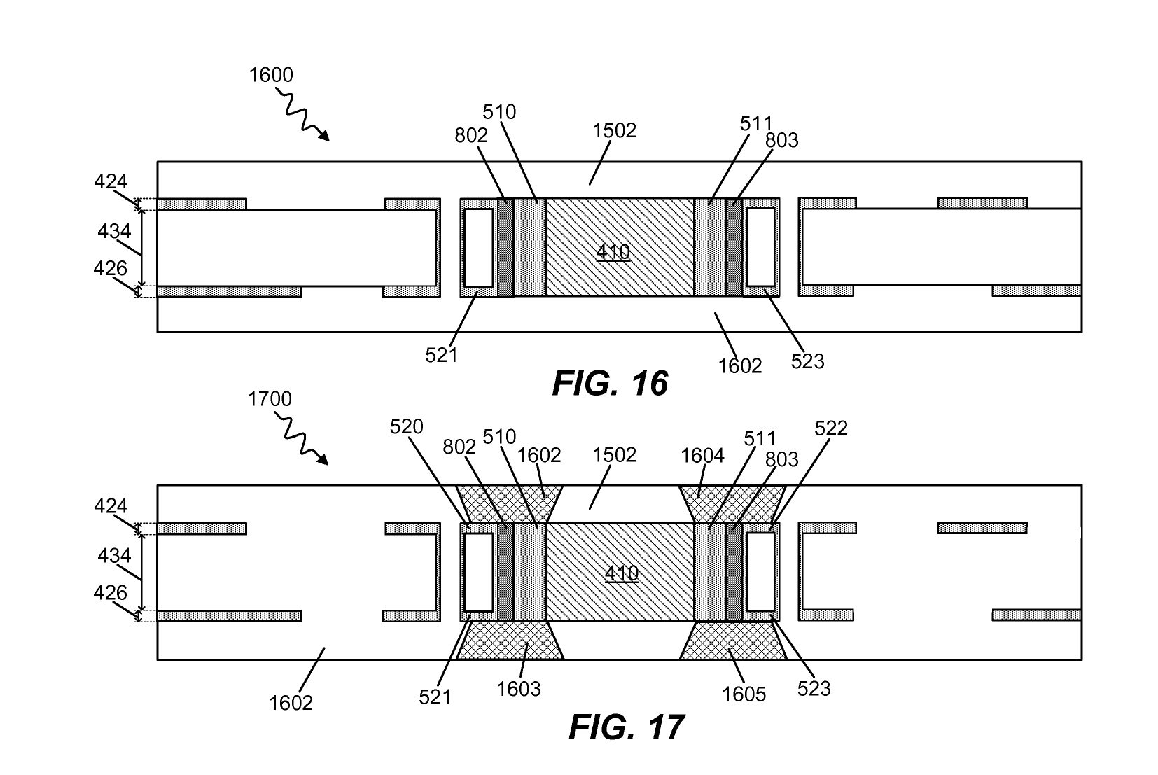

FIG. 16 illustrates the process in an intermediate manufacturing stage 1600 according to one aspect. As shown, the adhesive tape 1402 may be removed and surfaces such as traces within the second inner metal layer 426 may be cleaned. Next, another lamination step may be initiated that causes a dielectric material 1602, such as epoxy resin, to be deposited/formed and cured below the second inner metal layer 426, the DCC 410, the traces 521, 523, and the side platings 802, 803.

FIG. 17 illustrates the process in an intermediate manufacturing stage 1700 according to one aspect. As shown, one or more of DPR process steps may be used to form metal filled regions 1602, 1603, 1604, 1605 within the dielectric materials 1502, 1602 over and under the first and second electrodes 510, 511, the side platings 802, 803, and the traces 520, 521, 522, 523. The metal filled regions 1602, 1603, 1604, 1605 may contain a metal or metal alloy, such as but not limited to copper, aluminum, etc.

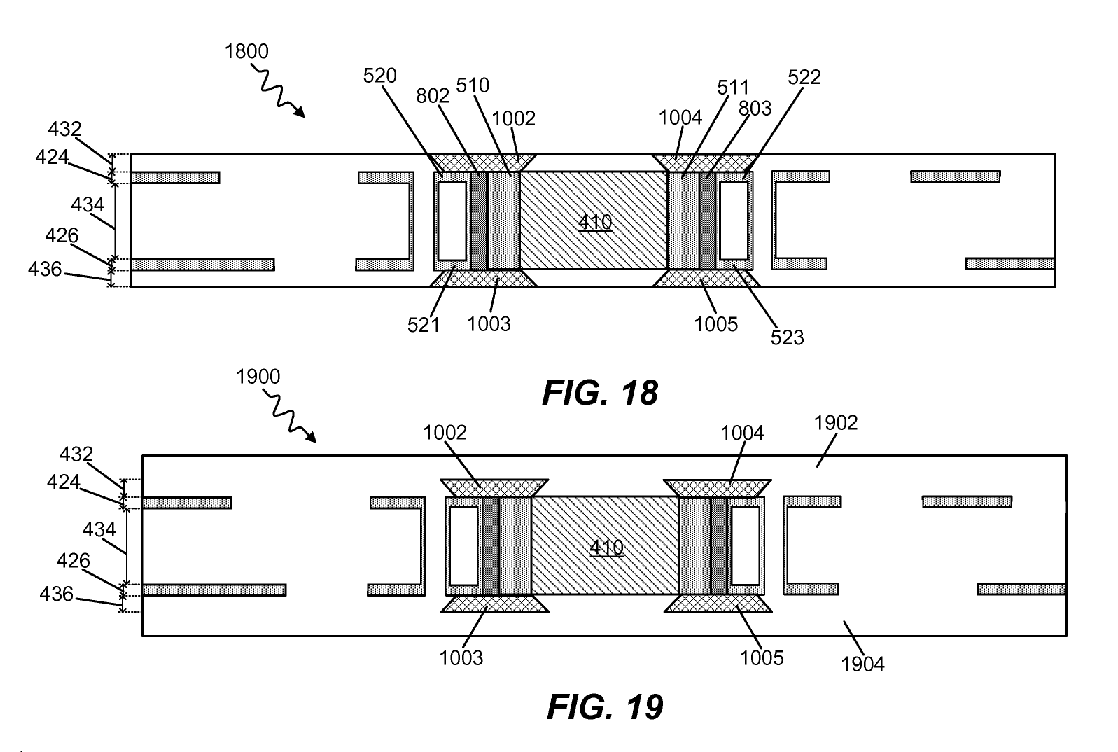

FIG. 18 illustrates the process in an intermediate manufacturing stage 1800 according to one aspect. As shown, a CMP process or other process may be used to grind down portions of the dielectric material 1502, 1602, and the metal filled regions 1602, 1603, 1604, 1605 so as to form extension pads 1002, 1003, 1004, 1005, the second insulator layer 432, and the third insulator layer 436. The extension pads 1002, 1003, 1004, 1005 are coupled to their respective electrodes 510, 511, side platings 802, 803, and traces 520, 521, 522, 523.

FIG. 19 illustrates the process in an intermediate manufacturing stage 1900 according to one aspect. As shown, one or more lamination steps may be initiated that causes a dielectric material 1902, such as epoxy resin, to be deposited/formed and cured above the extension pads 1002, 1004, and a dielectric material 1904, such as epoxy resin, to be deposited/formed and cured below the extension pads 1003, 1005.

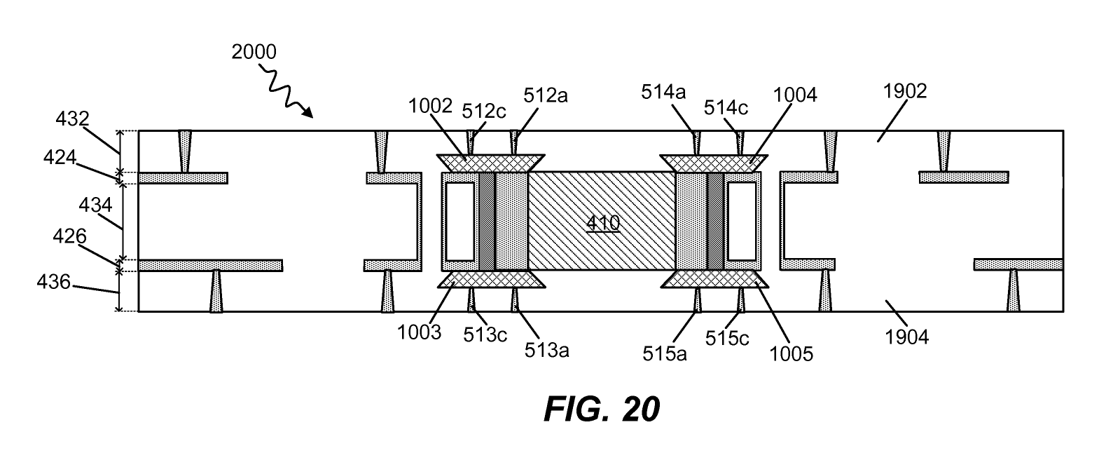

FIG. 20 illustrates the process in an intermediate manufacturing stage 2000 according to one aspect. As shown, one or more DPR process steps may be utilized to form vias 512a, 512c, 513a, 513c, 514a, 514c, 515a, 515c within the dielectric materials 1902, 1904. One end of the vias 512a, 512c, 513a, 513c, 514a, 514c, 515a, 515c electrically couple to the extension pads 1002, 1003, 1004, 1005 as shown.

FIG. 21 illustrates the process in a final manufacturing stage that forms the package substrate 2104. One or more DPR process steps may be utilized to form the first outer metal layer 422 having traces 516, 518, and the second outer metal layer 428 having traces 517, 519. A second end of the vias 512a, 512c, 513a, 513c, 514a, 514c, 515a, 515c is electrically coupled to the traces 516, 517, 518, 519 as shown.

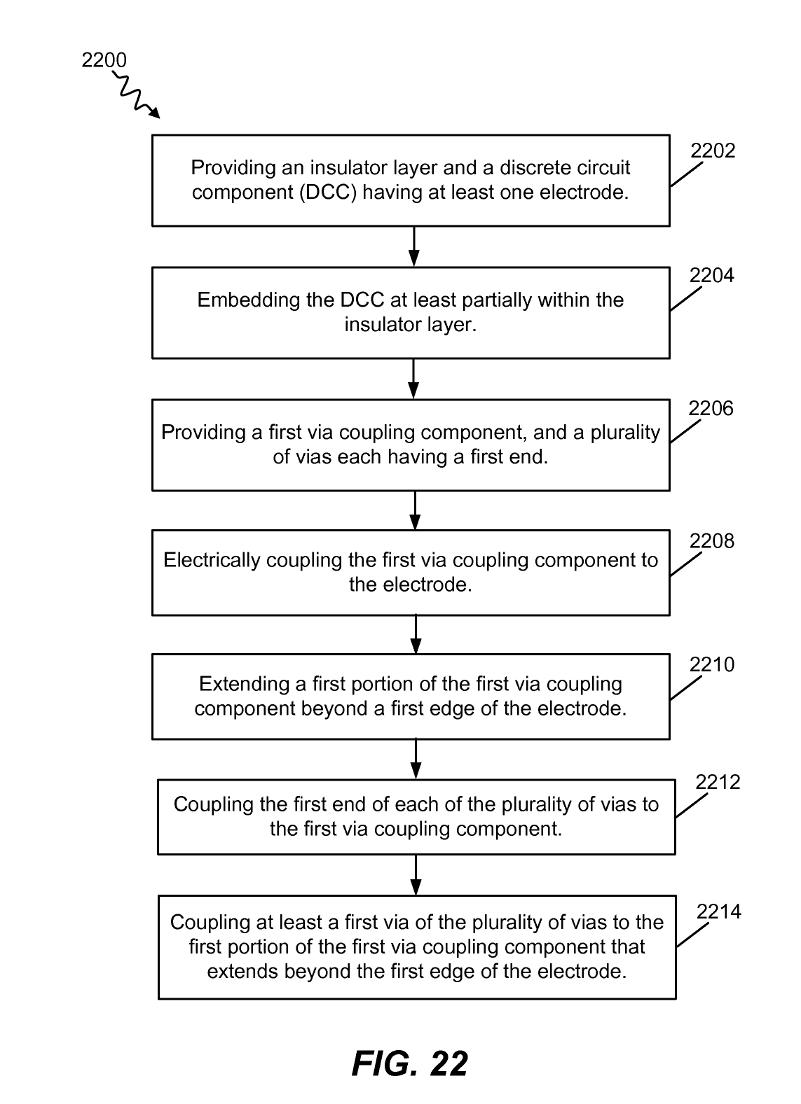

FIG. 22 illustrates a flowchart 2200 for a method of manufacturing a multi-layer package substrate of an integrated circuit package according to one aspect. At step 2202, the method includes providing an insulator layer and a discrete circuit component (DCC) having at least one electrode. At step 2204, the method includes embedding the DCC at least partially within the insulator layer. At step 2206, the method includes providing a first via coupling component, and a plurality of vias each having a first end. At step 2208, the method includes electrically coupling the first via coupling component to the electrode. At step 2210, the method includes extending a first portion of the first via coupling component beyond a first edge of the electrode. At step 2212, the method includes coupling the first end of each of the plurality of vias to the first via coupling component. At step 2214, the method includes coupling at least a first via of the plurality of vias to the first portion of the first via coupling component that extends beyond the first edge of the electrode.

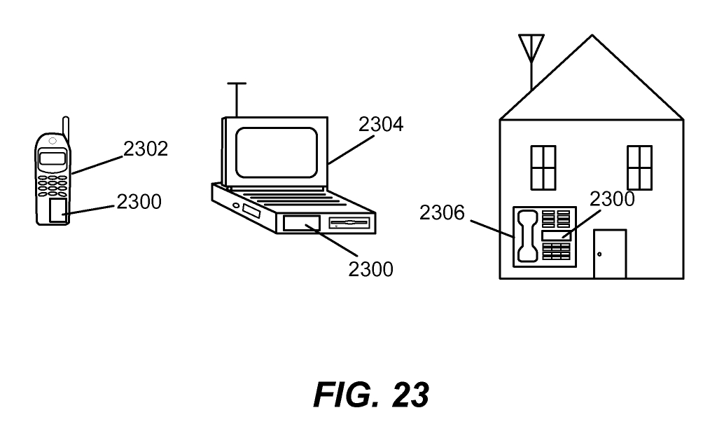

FIG. 23 illustrates various electronic devices that may include an integrated circuit 2300. The integrated circuit 2300 has a package substrate that may be any one of the package substrates 404, 804, 1006, 2104 described above. For example, a mobile telephone 2302, a laptop computer 2304, and a fixed location terminal 2306 may include the integrated circuit 2300. The devices 2302, 2304, 2306 illustrated in FIG. 23 are merely exemplary. Other electronic devices may also feature the integrated circuit 2300 including, but not limited to, hand-held personal communication systems (PCS) units, portable data units such as personal data assistants, GPS enabled devices, navigation devices, set top boxes, music players, video players, entertainment units, fixed location data units such as meter reading equipment, or any other device that stores or retrieves data or computer instructions, or any combination thereof.

One or more of the components, steps, features, and/or functions illustrated in FIGS. 4, 5, 6, 7, 8, 9, 10, 11, 12, 13, 14, 15, 16, 17, 18, 19, 20, 21, 22, and/or 23 may be rearranged and/or combined into a single component, step, feature or function or embodied in several components, steps, or functions. Additional elements, components, steps, and/or functions may also be added without departing from the invention.

Also, it is noted that the aspects of the present disclosure may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A multi-layer package substrate of an integrated circuit package, comprising:
a discrete circuit component (DCC) having at least one electrode, the DCC embedded at least partially within an insulator layer;
a first via coupling component electrically coupled to the electrode, a first portion of the first via coupling component extending beyond a first edge of the electrode; and
a plurality of vias each having a first end coupled to the first via coupling component, at least a first via of the plurality of vias coupled to the first portion of the first via coupling component extending beyond the first edge of the electrode.

2. The multi-layer package substrate of claim 1, wherein the first via coupling component increases an available surface area to which the first ends of the plurality of vias are coupled to.

3. The multi-layer package substrate of claim 1, wherein the plurality of vias includes three (3) or more vias.

4. The multi-layer package substrate of claim 1, wherein the plurality of vias each have a second end that are electrically coupled to a first outer metal layer, and at least a second portion of the first via coupling component is positioned within a first inner metal layer, wherein the first inner metal layer is closer to the insulator layer than the first outer metal layer.

5. The multi-layer package substrate of claim 1, wherein the first via coupling component is electrically coupled to a first metal trace within the first inner metal layer that is electrically coupled to a power or ground net.

6. The multi-layer package substrate of claim 5, further comprising:
a second via coupling component that is electrically coupled to the electrode, a first portion of the second via coupling component extending beyond a second edge of the electrode, at least a second portion of the second via coupling component positioned within a second inner metal layer, the second via coupling component electrically coupled to a second metal trace within the second inner metal layer that is electrically coupled to another power or ground net.

7. The multi-layer package substrate of claim 1, wherein the first via coupling component is an extension pad, the extension pad electrically coupled to a first surface of the electrode, the extension pad including at least one of a first overhang region that extends beyond a first edge of the electrode and/or a second overhang region that extends beyond a first widthwise edge of the electrode.

8. The multi-layer package substrate of claim 7, wherein the plurality of vias each have a second end that is electrically coupled to a first outer metal layer, a first portion of the extension pad extending beyond the first edge of the electrode, and at least a second portion of the extension pad is positioned within a first inner metal layer, the first inner metal layer closer to the insulator layer than the first outer metal layer.

9. The multi-layer package substrate of claim 7, wherein the extension pad is planar.

10. The multi-layer package substrate of claim 7, wherein the extension pad has at least one of a wider width than the electrode or a longer length than the electrode.

11. The multi-layer package substrate of claim 7, wherein the extension pad includes both the first overhang region that extends beyond the first edge of the electrode and the second overhang region that extends beyond the first widthwise edge of the electrode, the first widthwise edge perpendicular to the first edge, and the extension pad further includes a third overhang region that extends beyond a second widthwise edge of the electrode, the second widthwise edge positioned on an opposite side of the first widthwise edge of the electrode.

12. The multi-layer package substrate of claim 7, wherein the first ends of the plurality of vias are electrically coupled to a first surface of the extension pad, and the at least first via of the plurality of vias is coupled to at least one of the first overhang region and/or the second overhang region.

13. The multi-layer package substrate of claim 12, wherein a second surface of the extension pad is coupled to a first surface of a side plating, the side plating comprised of a metal, and a second surface of the side plating is coupled to a second surface of the electrode, the first surface of the side plating orthogonal to the second surface of the side plating, the first surface of the electrode orthogonal to the second surface of the electrode.

14. The multi-layer package substrate of claim 1, wherein the DCC is a multi-layer chip capacitor.

15. The multi-layer package substrate of claim 14, wherein the first via coupling component reduces an inductance between the electrode and an integrated circuit die of the integrated circuit package.

16. The multi-layer package substrate of claim 1, wherein the first via coupling component is a side plating having a first surface and a second surface, the electrode having a first surface and a second surface, the at least first via of the plurality of vias coupled to the first surface of the side plating, the second surface of the side plating electrically coupled to the second surface of the electrode, and at least a second via of the plurality of vias coupled to the first surface of the electrode.

17. The multi-layer package of claim 16, wherein the first surface and the second surface of the electrode are orthogonal to each other, and the first surface and the second surface of the side plating are orthogonal to each other.

18. The multi-layer package of claim 16, wherein the side plating is a metal alloy that comprises at least tin.

19. A method of manufacturing a multi-layer package substrate of an integrated circuit package, comprising:
providing an insulator layer, and a discrete circuit component (DCC) having at least one electrode;
embedding the DCC at least partially within the insulator layer;
providing a first via coupling component, and a plurality of vias each having a first end;
electrically coupling the first via coupling component to the electrode;
extending a first portion of the first via coupling component beyond a first edge of the electrode;
coupling the first end of each of the plurality of vias to the first via coupling component; and
coupling at least a first via of the plurality of vias to the first portion of the first via coupling component that extends beyond the first edge of the electrode.

20. The method of claim 19, further comprising:
increasing an available surface area to which the first ends of the plurality of vias couple to using the first via coupling component.

21. The method of claim 19, further comprising:
providing a first outer metal layer and a first inner metal layer;
electrically coupling a second end of each of the plurality of vias to the first outer metal layer; and
positioning at least a second portion of the first via coupling component within the first inner metal layer, wherein the first inner metal layer is closer to the insulator layer than the first outer metal layer.

22. The method of claim 19, further comprising:
providing a first metal trace within the first inner metal layer;
electrically coupling the first via coupling component to the first metal trace; and
electrically coupling the first metal trace to a power or ground net.

23. The method of claim 22, further comprising:
providing a second via coupling component;
electrically coupling the second via coupling component to the electrode;
extending a first portion of the second via coupling component beyond a second edge of the electrode;
providing a second inner metal layer and a second metal trace within the second inner metal layer;
positioning at least a second portion of the second via coupling component within the second inner metal layer;
electrically coupling the second via coupling component to the second metal trace; and
electrically coupling the second metal trace to another power or ground net.

24. The method of claim 19, wherein the first via coupling component is an extension pad, and the method further comprises:
electrically coupling the extension pad to a first surface of the electrode, the extension pad including at least one of a first overhang region that extends beyond a first edge of the electrode and/or a second overhang region that extends beyond a first widthwise edge of the electrode.

25. The method of claim 24, further comprising:
providing a first outer metal layer and a first inner metal layer;
electrically coupling a second end of each of the plurality of vias to the first outer metal layer;
extending a first portion of the extension pad beyond the first edge of the electrode; and
positioning at least a second portion of the extension pad within the first inner metal layer, the first inner metal layer closer to the insulator layer than the first outer metal layer.

26. The method of claim 24, wherein the extension pad includes both the first overhang region that extends beyond the first edge of the electrode and the second overhang region that extends beyond the first widthwise edge of the electrode, the first widthwise edge perpendicular to the first edge, and the extension pad further includes a third overhang region that extends beyond a second widthwise edge of the electrode, the second widthwise edge positioned on an opposite side of the first widthwise edge of the electrode.

27. The method of claim 24, further comprising:
electrically coupling the first ends of the plurality of vias to a first surface of the extension pad; and
coupling the at least first via of the plurality of vias to at least one of the first overhang region and/or the second overhang region.

28. The method of claim 27, further comprising:
providing a side plating;
coupling a second surface of the extension pad to a first surface of the side plating, the side plating comprised of a metal; and
coupling a second surface of the side plating to a second surface of the electrode, the first surface of the side plating orthogonal to the second surface of the side plating, the first surface of the electrode orthogonal to the second surface of the electrode.

29. The method of claim 19, wherein the DCC is a capacitor, and the first via coupling component reduces an inductance between the electrode and an integrated circuit die of the integrated circuit package.

30. The method of claim 19, wherein the first via coupling component is a side plating having a first surface and a second surface, the electrode having a first surface and a second surface, and the method further comprises:
coupling the at least first via of the plurality of vias to the first surface of the side plating;
electrically coupling the second surface of the side plating to the second surface of the electrode; and
coupling at least a second via of the plurality of vias to the first surface of the electrode.

31. The method of claim 30, wherein the first surface and the second surface of the electrode are orthogonal to each other, and the first surface and the second surface of the side plating are orthogonal to each other.

32. A multi-layer package substrate of an integrated circuit package, comprising:
a means for insulating;
a discrete circuit component (DCC) having at least one electrode, the DCC embedded at least partially within the means for insulating;
a first means for increasing surface area electrically coupled to the electrode, a first portion of the first means for increasing surface area extending beyond a first edge of the electrode; and
a plurality of vias each having a first end coupled to the first means for increasing surface area, at least a first via of the plurality of vias coupled to the first portion of the first means for increasing surface area extending beyond the first edge of the electrode.

33. The multi-layer package substrate of claim 32, wherein the first means for increasing surface area increases an available surface area to which the first ends of the plurality of vias are coupled to.

34. The multi-layer package substrate of claim 32, wherein the plurality of vias each have a second end that are electrically coupled to a first outer metal layer, and at least a second portion of the first means for increasing surface area is positioned within a first inner metal layer, wherein the first inner metal layer is closer to the means for insulating than the first outer metal layer.

35. The multi-layer package substrate of claim 32, wherein the first via coupling component is electrically coupled to a first metal trace within the first inner metal layer that is electrically coupled to a power or ground net.

36. The multi-layer package substrate of claim 35, further comprising:
a second means for increasing surface area that is electrically coupled to the electrode, a first portion of the second means for increasing surface area extending beyond a second edge of the electrode, at least a second portion of the second means for increasing surface area positioned within a second inner metal layer, the second means for increasing surface area electrically coupled to a second metal trace within the second inner metal layer that is electrically coupled to another power or ground net.
